(19) United States
(12) Patent Application Publication
(10) Pub. No.: US 2016/0222517 A1
(43) Pub. Date: Aug. 4, 2016

(54) METHODS OF MAKING A FLUOROELASTOMER COMPOSITION AND COMPOSITE ARTICLE

(71) Applicant: 3M INNOVATIVE PROPERTIES COMPANY, Saint Paul, MN (US)

(72) Inventors: Steven G. Corveleyn, Knokke-Heist (BE); An Van Royen, Melsele (BE)

(21) Appl. No.: 14/917,818

(22) PCT Filed: Sep. 12, 2014
(86) PCT No.: PCT/US2014/055423

§ 371 Date: Mar. 9, 2016

Related U.S. Application Data
(60) Provisional application No. 61/879,354, filed on Sep. 18, 2013.

(51) Int. Cl. C23C 16/56; C08K 3/36; C08K 5/14; C08K 3/26; C08K 3/34; C08K 3/16; C08K 3/30; C08K 9/04

(52) U.S. Cl. CPC C23C 16/56; C08K 3/30; C08K 3/36; C08K 9/04; C08K 3/26; C08K 3/34; C08K 3/16; C08K 5/14; C08K 2003/3045; C08K 2003/265

(57) ABSTRACT

A method of making a fluoroelastomer composition includes curing a fluoroelastomer precursor composition under ambient pressure conditions resulting in a fluoroelastomer composition that is substantially free of surface bubbles. The fluoroelastomer precursor composition includes peroxide-curable fluoropolymer, an effective amount of peroxide consisting essentially of bis(2,4-dichlorobenzoyl) peroxide for curing the peroxide-curable fluoropolymer. The fluoroelastomer precursor composition is essentially free of non-fluorinated carbon particles. A method of making composite articles based on the method is also disclosed.

### TECHNICAL FIELD

The present disclosure relates to fluoroelastomer compositions, composite article including them, and methods of making them.

### BACKGROUND

A fluoroelastomer composition is a rubbery composition that includes a crosslinked fluoropolymer and typically one or more fillers. Fluoroelastomer compositions may be prepared by combining a curable fluoropolymer with a curative and the optional filler to make a curable fluoroelastomer precursor composition, and then curing it. Many fluoroelastomer compositions are prepared by a free-radical cure mechanism initiated by a free-radical source (i.e., a free-radical curative) such as, for example, an organic peroxide, which decomposes upon heating to generate free-radicals.

Peroxide-curable fluoroelastomer precursor compositions are generally cured (vulcanized) under pressure (e.g., in a closed mold) to prevent foaming of the compositions during cure. Such foaming generally results in finished parts (e.g., o-rings, hoses, and gaskets) with degraded physical properties, which may even become unusable if the degradation in properties is severe enough. Because of this, continuous curing methods such as hot air tunnel curing or salt bath curing cannot be used, and the manufacturing operation needs to be discontinuous. Whether it is extrusion and autoclave curing, injection molding, or compression molding, finished part production methods always involve several steps. This makes the cost for producing a finished part using a fluoroelastomer composition more expensive than other elastomer types (e.g., silicone elastomers).

### SUMMARY

Bubbles form during curing of peroxide-curable fluoropolymer precursor compositions, because decomposition of the peroxide curing agent forms low molecular weight compounds (in addition to O₂), which evaporate under the conditions of curing causing surface bubbles during pressureless curing processes. The present inventors have found that the decomposition process can also be affected by fillers such as, e.g., carbon black that may be present.

The present inventors have discovered that the problem of surface bubbles can be solved by using bis(2,4-dichlorobenzoyl) peroxide as the peroxide curing agent during fluoroelastomer curing, especially if the fluoroelastomer composition is essentially free of non-fluorinated carbon particles. Extensive investigation has shown that bis(2,4-dichlorobenzoyl) peroxide is unique among commercially available peroxides in its ability to provide good curing of peroxide-curable fluoroelastomer compositions with little or no formation of surface bubbles.

In one aspect, the present disclosure provides a method of making a fluoroelastomer composition, the method comprising curing a fluoroelastomer precursor composition under ambient pressure conditions to provide the fluoroelastomer composition, wherein the fluoroelastomer precursor composition comprises:
at least one peroxide-curable fluoropolymer;
an effective amount of peroxide for curing the at least one peroxide-curable fluoropolymer, wherein said effective amount of peroxide consists essentially of bis(2,4-dichlorobenzoyl) peroxide,
   wherein the fluoroelastomer composition is essentially free of non-fluorinated carbon particles, and wherein the fluoroelastomer composition is substantially free of surface bubbles.

Fluoroelastomer compositions used in practice of the present disclosure are also advantageously used in manufacture of composite articles. Accordingly, in another aspect the present disclosure provides a method of making a composite article, the method comprising disposing a layer of a fluoroelastomer precursor composition according to the present disclosure, on at least a portion of at least one surface of a substrate and curing the fluoroelastomer precursor composition to provide a fluoroelastomer composition. And in another aspect, the present disclosure provides composite articles made according to the method.

Advantageously, methods and compositions according to the present disclosure enable continuous manufacturing of various fluoroelastomeric finished articles, which are currently done in batch processes.

As used herein, the term “ambient pressure” refers to pressure in the range of from 0.9 to 1.1 bar.

As used herein, the term “non-fluorinated carbon particles” refers to elemental carbon particles (e.g., carbon black particles) that have not been modified to include fluorine atoms.

As used herein, the term “substantially free of surface bubbles” means that at least 95 area percent of the surface (preferably at least 99 area percent of the surface) is free of bubbles having a maximum diameter larger than 0.5 mm (preferably free of bubbles larger than 0.3 mm, and more preferably free of bubbles larger than 0.1 mm) immediately adjacent to the surface, and free of surface cavities having a maximum dimension larger than 0.5 mm (preferably free of surface cavities having a maximum dimension larger than 0.3 mm, and more preferably free of surface cavities having a maximum dimension larger than 0.1 mm) extending inwardly and resulting from ruptured bubbles, combined.

As used herein, the term “substantially free of interior bubbles” means that at least 95 volume percent of the interior (preferably at least 99 volume percent of the interior) is free of bubbles having a maximum diameter larger than 0.5 millimeter (mm) (preferably free of bubbles having a maximum diameter larger than 0.3 mm, and more preferably free of bubbles having a maximum diameter larger than 0.1 mm).

As used herein, the term “fluoropolymer” refers to a polymer comprising fluorine atoms.

As used herein, the term “peroxide-curable” means curable by decomposition of an organic peroxide to generate free-radicals.

Features and advantages of the present disclosure will be further understood upon consideration of the detailed description as well as the appended claims.

### BRIEF DESCRIPTION OF THE DRAWING

FIG. 1 is a schematic side view of an exemplary composite article 100 according to the present disclosure.

It should be understood that numerous other modifications and embodiments can be devised by those skilled in the art, which fall within the scope and spirit of the principles of the disclosure. The FIGURE may not be drawn to scale.

### DETAILED DESCRIPTION

The present disclosure provides a method of making a fluoroelastomer composition under ambient conditions without excessive generation of bubbles/foam in the fluoroelastomer composition. The method is based on the discovery by the present inventors that peroxide-cured fluoroelastomers can be cured under ambient conditions using bis(2,4-dichlorobenzoyl) peroxide as the peroxide source without excessive bubble formation. This behavior appears to be unique among readily available peroxides that were evaluated. Accordingly, in practice of methods according to the present disclosure, the cured fluoroelastomer composition is substantially free of surface bubbles.

Fluoroelastomer compositions according to the present disclosure are typically prepared by heating a fluoroelastomer precursor composition in the presence of peroxide.

The fluoroelastomer precursor composition typically comprises a peroxide-curable fluoropolymer (e.g., a peroxide-curable fluoropolymer gum). In some embodiments, the peroxide-curable fluoropolymer comprises fluorine in an amount of at least 30 percent by weight, at least 40 percent by weight, at least 50 percent by weight, or even at least 60 percent by weight of fluorine. In some embodiments, the peroxide-curable fluoropolymer is perfluorinated.

The peroxide-curable fluoropolymer is typically made by interpolymerization of various ethylenically-unsaturated monomers; for example, as is known in the art. Examples of suitable monomers that can be interpolymerized to form a major amount of the peroxide-curable fluoropolymer include: perfluorinated olefins, vinylidene fluoride, non-fluorinated olefins, perfluorinated vinyl ethers (e.g., perfluorinated alkylvinyl ethers, perfluorinated alkoxyalkyl vinyl ethers, perfluorinated allyl ethers, perfluorinated polyether vinyl ethers), chlorotrifluoroethylene, vinyl fluoride, trifluoroethylene, and combinations thereof, preferably in combination with a minor amount of a cure site monomer that is reactive to free-radicals generated during peroxide curing. Those skilled in the art are capable of selecting specific interpolymerized monomer units at appropriate amounts to form an elastomeric polymer. Thus, the appropriate levels of interpolymerized monomer units are selected to achieve a fluoroelastomer.

Suitable perfluorinated olefins include, for example, those represented by the formula CF₂═CFR_{f}¹, where R_{f}¹ is fluorine or a perfluoroalkyl group having from 1 to 4 carbon atoms, preferably 1 to 3 carbon atoms. Preferred examples include tetrafluoroethylene and hexafluoropropylene.

Suitable nonfluorinated olefins are preferably alpha-olefins having from 1 to 12 carbon atoms, more preferably 1 to 4 carbon atoms. Specific examples include ethylene and propylene.

Suitable perfluorinated alkyl vinyl ethers include, for example, CF₂═CFOCF₃, CF₂═CFOCF₂CF₂CF₃, CF₂═CFOCF₂CF₃, CF₂═CFOCF(CF₃)CF₃, and CF₂═CFOCF₂CF₂CF₂CF₂CF₃.

Suitable perfluorinated alkoxyalkyl vinyl ethers include, for example, CF₂═CFOCF₂CF₂OCF₃, CF₂═CFOCF₂CF₂CF₂CF₂OCF₃, CF₂═CFOCF₂OCF₂CF₃, CF₂═CFOCF₂CF₂OCF₂CF₃, CF₂═CFOCF₂CF₂CF₂OCF₂CF₃, CF₂═CFOCF₂CF₂CF₂CF₂OCF₂CF₃, CF₂═CFOCF₂CF₂OCF₂OCF₃, CF₂═CFOCF₂CF₂OCF₂CF₂OCF₃, CF₂═CFOCF₂CF₂OCF₂CF₂CF₂OCF₃, CF₂═CFOCF₂CF₂OCF₂CF₂CF₂CF₂OCF₃, CF₂═CFOCF₂CF₂OCF₂CF₂CF₂CF₂CF₂OCF₃, CF₂═CFOCF₂CF₂(OCF₂)₃OCF₃, CF₂═CFOCF₂CF₂(OCF₂)₄OCF₃, CF₂═CFOCF₂CF₂OCF₂OCF₂OCF₃, CF₂═CFOCF₂CF₂OCF₂CF₂CF₃, and CF₂═CFOCF₂CF₂OCF₂CF₂OCF₂CF₂CF₃.

Suitable perfluorinated allyl ethers include, for example, CF₂═CFCF₂OCF₂CF₂OCF₃, CF₂═CFCF₂OCF₂CF₂CF₂OCF₃, CF₂═CFCF₂OCF₃, CF₂═CFCF₂OCF₂CF₂CF₃, CF₂═CFCF₂OCF₂CF₂OCF₃, and CF₂═CFCF₂OCF₂OCF₃.

Suitable perfluorinated polyether vinyl ethers include, for example, those represented by the formula CF₂═CFO(CF₂)ₘ(O(CF₂)ₚ)ₙOR_{f}² wherein R_{f}² is a perfluoroalkyl group having from 1 to 4 carbon atoms, m=1-4, n=0-6, and p=1-2.

Preferably, the peroxide-curable fluoropolymer has an effective amount of cure sites, preferably such that it has a Mooney viscosity of 4 or less (ML 1+10) at 100° C. according to ASTM test method D1646-06 TYPE A, and in some embodiments a Mooney viscosity of 2 or less (ML 1+10) at 100° C. according to ASTM test method D1646-06 TYPE A. The cure sites may be introduced, for example, by interpolymerization of cure-site monomers containing iodo, bromo, and/or cyano groups.

Suitable bromine-based and iodine-based cure-site monomers include, for example, compounds represented by the formula CX₂═CXZ, wherein X represents H or F, and Z represents I, Br, or R_{f}³—X wherein X represents I or Br, and R_{f}³ represents a perfluorinated or partially perfluorinated alkylene group, optionally substituted with one or more catenated oxygen (—O—) atoms. In addition, nonfluorinated bromo- or iodo-olefins (e.g., vinyl bromide, vinyl iodide, or allyl iodide) can be used. In some embodiments, cure-site monomers are derived from one or more compounds selected from CH₂═CHI, CF₂═CHI, CF₂═CFI, CH₂═CHCH₂I, CF₂═CFCF₂I, CH₂═CHCF₂CF₂I, CF₂═CFCH₂CH₂I, CF₂═CFCF₂CF₂I, CH₂═CH(CF₂)₆CH₂CH₂I, CF₂═CFOCF₂CF₂I, CF₂═CFOCF₂CF₂CF₂I, CF₂═CFOCF₂CF₂CH₂I, CF₂═CFCF₂OCH₂CH₂I, CF₂═CFO(CF₂)₃OCF₂CF₂I, CH₂═CHBr, CF₂═CHBr, CF₂═CFBr, CH₂═CHCH₂Br, CF₂═CFCF₂Br, CH₂═CHCF₂CF₂Br, CF₂═CFOCF₂CF₂Br.

In some embodiments, the weight percent of iodine in the fluoropolymer may range from about 0.2 percent by weight to about 2 percent by weight, and preferably from about 0.3 percent by weight to about 1 percent by weight.

Useful nitrogen-containing cure site monomers include nitrile-containing fluorinated olefins and nitrile-containing fluorinated vinyl ethers, such as: CF₂═CFO(CF₂)_{L}CN; CF₂═CFO[CF₂CF(CF₃)O]_{q}(CF₂O)_{y}CF(CF₃)CN; CF₂═CF[OCF₂CF(CF₃)]ᵣO(CF₂)ₜCN; and CF₂═CFO(CF₂)ᵤOCF(CF₃)CN, wherein L=2-12; q═0-4; r═1-2; y═0-6; t═1-4; and a═2-6. Representative examples of such monomers include CF₂═CFO(CF₂)₃OCF(CF₃)CN, perfluoro(8-cyano-5-methyl-3,6-dioxa-1-octene), and CF₂═CFO(CF₂)₅CN.

Cure-site monomer is preferably incorporated in the fluoropolymer in an amount that is effective to achieve the desired results. The amount of cure-site monomer in the fluoropolymer preferably is at least about 0.01 mole percent, and more preferably at least about 0.1 mole percent, based on the total moles of monomer used to prepare the fluoropolymer. The amount of cure-site monomer in the fluoropolymer preferably is less than about 10 mole percent, and more preferably below about 5 mole percent. For example, the amount of cure-sire monomer incorporated in the fluoropolymer may be from 0.1 to 5 mole percent, based on the total moles of monomer used to prepare the fluoropolymer.

Alternatively, or in addition, cure-site functional group such as iodine atoms or cyano groups may be present as end-group(s) of the fluoropolymer backbone; for example, as described in U.S. Pat. No. 6,166,157 (Hung et al.) and U.S. Pat. Appln. Publ. No. 2010/0286329 A1 (Fukushi et al.).

Polymerization of the monomers to form the fluoropolymer can be carried out according to polymerization procedures known in the art; for example, as described in U.S. Pat. Appln. Publ. No. 2012/0088884 A1 (Fukushi et al.).

If the peroxide-curable fluoropolymer is perhalogenated, preferably perfluorinated, it preferably contains at least 50 mole percent (mole percent), at least 60 mole percent, or even at least 65 mol % of its interpolymerized monomer units derived from TFE and/or CTFE, optionally including HFP. The balance of the interpolymerized monomer units of the fluoropolymer (e.g., up to 50 mole percent) is preferably made up of one or more perfluorinated alkyl vinyl ethers and/or perfluorinated alkoxyalkyl vinyl ethers, and from about 0.1 mole percent to about 5 mole percent, preferably from about 0.3 mole percent to about 2 mole percent, of a suitable cure site monomer. An exemplary fluoropolymer is composed of principal monomer units of TFE and at least one perfluorinated alkyl vinyl ether. In such copolymers, the copolymerized perfluorinated ether units preferably constitute from about 10 to about 50 mole percent, and more preferably from about 15 to about 35 mole percent of total monomer units present in the polymer.

If the fluoropolymer is not perfluorinated, it preferably contains from about 5 mole percent to about 90 mole percent of interpolymerized monomer units derived from TFE, CTFE, and/or HFP, from about 5 mole percent to about 90 mole percent of its interpolymerized monomer units derived from VDF, ethylene, and/or propylene, up to about 40 mole percent of its interpolymerized monomer units derived from a vinyl ether, and from about 0.1 mole percent to about 5 mole percent, preferably from about 0.3 mole percent to about 2 mole percent, of a suitable cure site monomer.

Suitable perfluorinated polyether olefins include, for example, those represented by the formula CF₂═CF(CF₂)ₖOR_{f}⁴, wherein k=1-4, and R_{f}⁴ represents a perfluoroalkyl group having from 1 to 4 carbon atoms.

Perfluorinated polyethers may be pre-emulsified with an emulsifier prior to copolymerization with other monomers.

Typically, the fluoroelastomer precursor composition comprises an effective amount of peroxide comprising bis(2,4-dichlorobenzoyl) peroxide for curing the fluoroelastomer precursor composition. Typically, the amount of peroxide is in the range of from 0.1 to 10 percent by weight, preferably 1 to 8 percent by weight, more preferably from 1 to 5 percent by weight, based on the total weight of the fluoroelastomer precursor composition, although other amounts may also be used. Preferably, the peroxide consists essentially of bis(2,4-dichlorobenzoyl) peroxide. That is, some additional peroxide(s), may be included with the bis(2,4-dichlorobenzoyl) peroxides provided that they do not cause excessive bubble formation during cure under ambient conditions. Preferably, the peroxide includes at least 80 percent by weight of bis(2,4-dichlorobenzoyl) peroxide, more preferably at least 90 percent by weight, more preferably at least 95 percent by weight, and more preferably more preferably at least 99 percent by weight, based on the total weight of peroxide present.

Filler (i.e., one or more particulate fillers) may be included in the fluoroelastomer precursor composition, resulting in its inclusion in the fluoroelastomer after curing. The filler may reduce cost, and/or improved physical properties of the fluoroelastomer. If present, the filler is preferably present in an amount of from 0.1 to 50 percent by weight, more preferably from 5 to 45 percent by weight, and even more preferably from 10 to 40 percent by weight, based on the total weight of the fluoroelastomer precursor composition.

Examples of suitable fillers include alkali metal carbonates (e.g., sodium carbonate, and potassium carbonate), alkali metal sulfates (e.g., sodium sulfate, potassium sulfate, and combinations thereof), alkaline earth metal carbonates (e.g., magnesium carbonate, calcium carbonate, strontium carbonate, barium carbonate, and combinations thereof), alkaline earth metal sulfates (e.g., magnesium sulfate, calcium sulfate, strontium sulfate, barium sulfate, and combinations thereof), alkali metal oxides (e.g., sodium oxide, potassium oxide, and combinations thereof), alkaline earth metal oxides (e.g., magnesium oxide, calcium oxide, strontium oxide, barium oxide, and combinations thereof), titanium oxides, silicon oxides (e.g., silica), alkali metal silicates (e.g. sodium silicate), alkaline earth silicates (e.g., magnesium silicate, hydrated magnesium silicate (talc), and combinations thereof), fluorinated carbon particles (e.g., fluorinated carbon blacks), and combinations thereof. Addition of hygroscopic fillers (e.g., calcium oxide) may be beneficial to reduce bubbles due to water vapor.

Preferably, the fluoroelastomer precursor composition is essentially free of acidic fillers. In some embodiments, the fluoroelastomer precursor composition is essentially free of acidic filler (e.g., the fluoroelastomer precursor composition comprises less than 0.5 percent by weight of acidic fillers, or even less than 0.1 percent by weight of acidic fillers, based on the total weight of the fluoroelastomer precursor composition).

In order to minimize bubble formation during cure, the present inventors have discovered that it is typically desirable to limit the usage of non-fluorinated carbon particles in the fluoroelastomer precursor composition as they tend to increase the formation of bubbles. Accordingly, the fluoroelastomer precursor composition (and typically also the fluoroelastomer composition) is preferably essentially free of non-fluorinated carbon particles fillers (e.g., non-fluorinated carbon particles fillers). As used herein, the term “essentially free of non-fluorinated carbon particles” means containing less than 5 percent by weight, preferably less than 1 percent by weight, more preferably less than 0.1 percent by weight, or even free of non-fluorinated carbon particles, based on the total weight of the fluoroelastomer precursor composition or fluoroelastomer composition, as appropriate. Examples of non-fluorinated carbon particles include thermal black, lampblack, acetylene black, furnace black, and channel black.

The fluoroelastomer precursor composition may be compounded using known techniques such as, for example, using a two-roll mill, although any method capable of mixing its components may be used.

Peroxide curing of the fluoroelastomer precursor composition is preferably carried out by heating the fluoroelastomer precursor composition at one or more temperatures in the range of from 40° C. to 150° C., preferably from 40° C. to 100° C., although this is not a requirement.

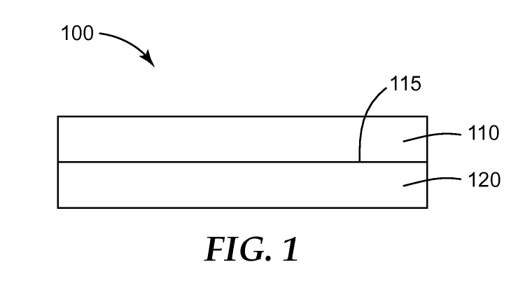

Advantageously, peroxide curing of the fluoroelastomer precursor composition is preferably carried out under ambient pressure conditions; however, higher or lower pressures may also be used. This leads to several beneficial processing options in comparison to conventional methods. For example, methods according to the present disclosure may be used to make composite articles. In some embodiments, the fluoroelastomer precursor composition may be disposed on at least a portion of one or more surfaces of a substrate (e.g., as a layer on a carrier film, sheet, or web) prior to curing at ambient precursor. Subsequent curing results in a composite article. Referring now to FIG. 1, exemplary composite article 100 comprises layer of fluoroelastomer composition 110 disposed on surface 115 of substrate 120. The fluoropolymer composition may be removably bonded to the substrate (mechanically removable without damaging the substrate) or securely bonded (e.g., chemically bonded) to the substrate, for example, if it has surface groups that can react with free radicals generated through peroxide curing of the fluoroelastomer precursor composition. Composite articles prepared according to the present disclosure may be converted into other useful forms; for example, by removing the substrate from the layer of the fluoroelastomer composition, optionally with cutting, to form a gasket, sheet, or membrane. Cutting or other shaping may also be performed prior to the peroxide curing step.

In some embodiments, the fluoroelastomer precursor composition is placed in an open mold prior to curing at ambient pressure. In some embodiments, the fluoroelastomer precursor composition is extruded (e.g., as a tube/hose) and then cured at ambient pressure. The process of shaping and/or curing the fluoroelastomer precursor composition may be continuous or batch-wise.

### SELECT EMBODIMENTS OF THE PRESENT DISCLOSURE

In a first embodiment, the present disclosure provides a method of making a fluoroelastomer composition, the method comprising curing a fluoroelastomer precursor composition under ambient pressure conditions to provide the fluoroelastomer composition, wherein the fluoroelastomer precursor composition comprises:
at least one peroxide-curable fluoropolymer;
an effective amount of peroxide for curing the at least one peroxide-curable fluoropolymer, wherein said effective amount of peroxide consists essentially of bis(2,4-dichlorobenzoyl) peroxide,
wherein the fluoroelastomer composition is essentially free of non-fluorinated carbon particles, and wherein the fluoroelastomer composition is substantially free of surface bubbles.

In a second embodiment, the present disclosure provides a method according to the first embodiment, wherein the fluoroelastomer precursor composition further comprises at least one filler selected from the group consisting of alkali metal carbonates, alkali metal sulfates, alkaline earth metal carbonates, alkaline earth metal sulfates, alkali metal oxides, alkaline earth metal oxides, titanium oxides, silicon oxides, alkali metal silicates, alkaline earth silicates, fluorinated carbon particles, and combinations thereof.

In a third embodiment, the present disclosure provides a method according to the second embodiment, wherein the filler comprises talc.

In a fourth embodiment, the present disclosure provides a method according to the second or third embodiment, wherein the filler comprises fluorinated carbon particles.

In a fifth embodiment, the present disclosure provides a method according to any one of the first to fourth embodiments, wherein the peroxide-curable fluoroelastomer precursor composition comprises a fluoropolymer comprising interpolymerized monomer units, and wherein the monomer units comprise at least one of tetrafluoroethylene, vinylidene fluoride, hexafluoropropylene, ethylene, propylene, perfluorinated alkyl vinyl ethers, perfluorinated allyl ethers, chlorotrifluoroethylene, vinyl fluoride, and trifluoroethylene.

In a sixth embodiment, the present disclosure provides a method according to any one of the first to fifth embodiments, wherein said curing the fluoroelastomer precursor composition is effected by heating the fluoroelastomer precursor composition at at least one temperature in the range of from 40° C. to 150° C.

In a seventh embodiment, the present disclosure provides a method according to any one of the first to sixth embodiments, wherein said curing of the fluoroelastomer precursor composition occurs at a pressure in the range of from 0.9 to 1.1 bar.

In an eighth embodiment, the present disclosure provides a method according to any one of the first to seventh embodiments, wherein the fluoroelastomer precursor composition is essentially free of carbon black.

In a ninth embodiment, the present disclosure provides a method of making a fluoroelastomer composition according to any one of the first to eighth embodiments, wherein the fluoroelastomer composition is substantially free of interior bubbles.

In a tenth embodiment, the present disclosure provides a method of making a fluoroelastomer composition according to any one of the first to ninth embodiments, wherein said curing the fluoroelastomer precursor composition is carried out in a hot air tunnel.

In an eleventh embodiment, the present disclosure provides a method of making a fluoroelastomer composition according to any one of the first to tenth embodiments, further comprising extruding the fluoroelastomer precursor composition.

In a twelfth embodiment, the present disclosure provides a method of making a fluoroelastomer composition according to any one of the first to tenth embodiments, wherein said curing the fluoroelastomer precursor composition is carried out in an open mold.

In a thirteenth embodiment, the present disclosure provides a method of making a composite article, the method comprising:
disposing a layer of a fluoroelastomer precursor composition on at least a portion of at least one surface of a substrate, wherein the fluoroelastomer precursor composition comprises:
   at least one peroxide-curable fluoropolymer;
   an effective amount of peroxide for curing the at least one peroxide-curable fluoropolymer, wherein said effective amount of peroxide consists essentially of bis(2,4-dichlorobenzoyl) peroxide,
   wherein the fluoroelastomer composition is essentially free of non-fluorinated carbon particles; and
      curing the fluoroelastomer precursor composition to provide a fluoroelastomer composition, wherein the fluoroelastomer composition is substantially free of surface bubbles.

In a fourteenth embodiment, the present disclosure provides a method of making a composite article according to the thirteenth embodiment, wherein the substrate comprises a carrier film.

In a fifteenth embodiment, the present disclosure provides a method of making a composite article according to the thirteenth embodiment, wherein the substrate comprises a gasket or a tube.

In a sixteenth embodiment, the present disclosure provides a method of making a composite article according to any one of the thirteenth to fifteenth embodiments, wherein the fluoroelastomer precursor composition further comprises at least one filler selected from the group consisting of alkali metal carbonates, alkali metal sulfates, alkaline earth metal carbonates, alkaline earth metal sulfates, alkali metal oxides, alkaline earth metal oxides, titanium oxides, silicon oxides, alkali metal silicates, alkaline earth silicates, fluorinated carbon particles, and combinations thereof.

In a seventeenth embodiment, the present disclosure provides a method of making a composite article according to the sixteenth embodiment, wherein the filler comprises talc.

In an eighteenth embodiment, the present disclosure provides a method of making a composite article according to the sixteenth or seventeenth embodiment, wherein the filler comprises fluorinated carbon particles.

In a nineteenth embodiment, the present disclosure provides a method of making a composite article according to any one of the sixteenth to eighteenth embodiments, wherein the peroxide-curable fluoroelastomer precursor composition comprises a fluoropolymer comprising interpolymerized monomer units, and wherein the monomer units comprise at least one of tetrafluoroethylene, vinylidene fluoride, hexafluoropropylene, ethylene, propylene, perfluorinated alkyl vinyl ethers, perfluorinated allyl ethers, chlorotrifluoroethylene, vinyl fluoride, and trifluoroethylene.

In a twentieth embodiment, the present disclosure provides a method of making a composite article according to any one of the sixteenth to nineteenth embodiments, wherein said curing the fluoroelastomer precursor composition is effected by heating the fluoroelastomer precursor composition at at least one temperature in the range of from 40° C. to 150° C.

In a twenty-first embodiment, the present disclosure provides a method of making a composite article according to any one of the sixteenth to twentieth embodiments, wherein said curing of the fluoroelastomer precursor composition occurs at a pressure in the range of from 0.9 to 1.1 bar.

In a twenty-second embodiment, the present disclosure provides a method of making a composite article according to any one of the sixteenth to twenty-first embodiments, wherein the fluoroelastomer precursor composition is essentially free of non-fluorinated carbon particles.

In a twenty-third embodiment, the present disclosure provides a method of making a composite article according to any one of the sixteenth to twenty-second embodiments, wherein the fluoroelastomer composition is substantially free of interior bubbles.

Objects and advantages of this disclosure are further illustrated by the following non-limiting examples, but the particular materials and amounts thereof recited in these examples, as well as other conditions and details, should not be construed to unduly limit this disclosure.

### EXAMPLES

Unless otherwise noted, all parts, percentages, ratios, etc. in the Examples and the rest of the specification are by weight.

The following abbreviations are used in the examples: EX=Example, CE=Comparative Example, phr=parts per hundred by weight, g=grams, min=minutes, hr=hour, ° C.=degrees Celsius, psi=pounds per square inch, MPa=megapascals, and dN-m=decinewton-meter, HFP=hexafluoropropylene, VDF=vinylidene difluoride.

Table 1 (below) lists materials used in the Examples.

TABLE 1

| MATERIAL | DESCRIPTION AND SOURCE |
|---|---|
| FLUORO- | ultra low viscosity HFP/VDF peroxide-curable iodine- |
| POLYMER A | containing fluoropolymer made as described in the |
| | section headed “FLUOROPOLYMER A |
| | PREPARATION” hereinbelow. |
| FLUORO- | peroxide-curable fluoropolymer having a TR-10 |
| POLYMER B | of −19° C., and containing one weight percent |
| | HYDROTALCITE DHT-A (from Kisuma Chemicals bv, |
| | Veendam, The Netherlands) filler, available as DYNEON |
| | FPO 3520 FLUOROELASTOMER from 3M Company. |
| FLUORO- | peroxide-curable fluoropolymer having a TR-10 |
| POLYMER C | of −40° C., available as DYNEON |
| | FLUOROELASTOMER LTFE-6400Z from 3M |
| | Company. |
| FLUORO- | peroxide-curable TFE/VDF/H FP terpolymer |
| POLYMER D | fluoropolymer, available as DYNEON PEROXIDE |
| | CURE FLUOROELASTOMER FPO-3740 from 3M |
| | Company. |
| FLUORO- | fluoropolymer commercially available as DYNEON PFE |
| POLYMER E | 90X PERFLUOROELASTOMER from 3M Company. |
| CaO | Calcium oxide powder, from Sigma-Aldrich Company, |
| | Saint Louis, Missouri. |
| ZEOLITE 4A | 4 Angstrom (0.4 nm) pore size zeolite molecular sieves, |
| | available as PURMOL 4ST zeolite from Zeochem AG, |
| | Uetikon, Switzerland. |
| PROCESS AID | blend of fatty acid derivatives and waxes available as |
| | STRUKTOL HT290 from Struktol Company of America, |
| | Stow, Ohio |
| PEROXIDE A | bis(2,4-dichlorobenzoyl) peroxide paste, 50% in silicone |
| | oil, available as PERKADOX PD50S from Akzo-Nobel |
| | N.V. |
| PEROXIDE B | 2,5-dimethyl-2,5-di(tert-butylperoxy)hexane 50% on |
| | silica, available as TRIGONOX 101-50D-PD from |
| | Akzo-Nobel N.V. |
| PEROXIDE C | dicumyl peroxide powder, 40% on calcium carbonate, |
| | available as PERKADOX BC-40B-PD from Akzo Nobel |
| | N.V. |
| PEROXIDE D | dibenzoyl peroxide, 50% in silicone oil, available as |
| | LUCIDOL S-50S-PS from Akzo Nobel, N.V. |
| COAGENT | triallyl isocyanurate (TAIC), 70%, available from |
| | Lehmann & Voss & Co, Hamburg, Germany |
| BS | barium sulfate, available from Sachtleben, Duisberg, |
| | Germany |
| Silica | 5-micron white crystalline silica, available under the |
| | trade designation MINUSIL-5 from US Silica, Berkley |
| | Springs, West Virginia |
| CaSil | 3.5-micron (D₅₀) epoxysilane surface-treated |
| | Wollastonite commercially available as TREMIN |
| | 283-600-EST from Quarzwerke, Frechen, Germany |
| Talc | Talc (magnesium silicate), available as MISTRON |
| | VAPOR from Imerys, Paris, France |
| CaCO₃ | Calcium carbonate, available as SOCAL P2 from Solvay, |
| | Brussels, Belgium |
| FC | Fluorinated carbon particles, available as |
| | CARBOFLUOR 2065 from Advanced Research |
| | Chemicals Inc, Catoosa, Oklahoma |

### Fluoropolymer A Preparation

An 80-liter reactor was charged with 52 kg of water, 40 g of ammonium persulfate, and 160 g of a 50% aqueous solution of potassium phosphate dibasic. The reactor was evacuated, the vacuum was broken, and it was pressurized with nitrogen to 25 psi (0.17 MPa). This vacuum and pressurization was repeated three times. After removing oxygen, the reactor was heated to 80° C. and pressurized to 74 psi (0.51 MPa) with a blend of hexafluoropropylene, 1,4-diiodooctafluorobutane (commercially available from SynQuest Labs, Alachua, Fla.) and decafluoro-3-methoxy-4-trifluoromethyl-pentane (Sigma-Aldrich Company, Saint Louis, Mo.). To prepare the blend of hexafluoropropylene, 1,4-diiodooctafluorobutane and 3-ethoxy-1,1,1,2,3,4,4,5,5,6,6,6-dodecafluoro-2-trifluoromethylhexane (available as 3M NOVEC HFE 7500 ENGINEERED FLUID from 3M Company), a 1-liter stainless steel cylinder was evacuated and purged 3 times with nitrogen. After adding the 1,4-diiodooctafluorobutane and 3-ethoxy-1,1,1,2,3,4,4,5,5,6,6,6-dodecafluoro-2-trifluoromethylhexane to the cylinder, the hexafluoropropylene was added based on the amount of 1,4-diiodooctafluorobutane added. The blend was then attached to the reactor and was fed using a blanket of nitrogen. The blend contained 89.9 weight percent of hexafluoropropylene, 2.5 weight percent of 1,4-diiodooctafluorobutane and 7.6 weight percent of 3-ethoxy-1,1,1,2,3,4,4,5,5,6,6,6-dodecafluoro-2-trifluoromethylhexane. The reactor was then charged with vinylidene difluoride and the above described blend of hexafluoropropylene, 1,4-diiodooctafluorobutane and 3-ethoxy-1,1,1,2,3,4,4,5,5,6,6,6-dodecafluoro-2-trifluoromethylhexane, bringing reactor pressure to 200 psi (1.38 MPa). Total pre-charge of vinylidene difluoride and the blend of hexafluoropropylene, 1,4-diiodooctafluorobutane and 3-ethoxy-1,1,1,2,3,4,4,5,5,6,6,6-dodecafluoro-2-trifluoromethylhexane was 800 g, and 1536 g, respectively. The reactor was agitated at 450 rpm. As reactor pressure dropped due to monomer consumption in the polymerization reaction, the blend of hexafluoropropylene, 1,4-diiodooctafluorobutane and 3-ethoxy-1,1,1,2,3,4,4,5,5,6,6,6-dodecafluoro-2-trifluoromethylhexane, and vinylidene difluoride was continuously fed to the reactor to maintain the pressure at 220 psi (1.52 MPa). The ratio of the blend to vinylidene difluoride was 0.651 by weight and no emulsifier was used for the polymerization. After 6.2 hours the monomer and blend feeds were discontinued and the reactor was cooled. The resulting dispersion had a solid content of 29.7 percent by weight and a pH of 3.6. The dispersion particle size was 323 nm and the total amount of dispersion was 76.5 kg.

For the coagulation, 19.54 g of a mixture of 1 part by weight of ammonium hydroxide and 25 parts by weight of deionized water was added to 942 g of the latex made as described above. The pH of the mixture was 6.7. This mixture was added to 2320 mL of a 5 percent by weight magnesium chloride in water solution. The crumb was recovered by filtering the coagulate through cheese cloth and gently squeezing to remove excess water. The crumb was returned to the coagulation vessel and rinsed with deionized water a total of 3 times. After the final rinse and filtration, the crumb was dried in a 130° C. oven for 16 hours. The resulting fluoropolymer raw gum (FLUOROPOLYMER A) had a Mooney viscosity of 2.5 at 121° C.

The Mooney viscosity was measured as per ASTM D1646-06 “Standard Test Methods for Rubber-Viscosity, Stress Relaxation, and Pre-Vulcanization Characteristics (Mooney Viscometer)”, Type A, using a MV2000 instrument (available from Alpha Technologies, Ohio) using large rotor (ML 1+10) at 121° C. Results are reported in Mooney units. The fluoropolymer by neutron activation analysis (NAA) contained 0.63 percent by weight of iodine. The fluoropolymer, by FT-IR analysis, contained 80.2 mole percent of copolymerized monomer units of vinylidene difluoride and 19.8 mole percent of hexafluoropropylene.

### Cure Rheology Testing

Cure rheology tests were carried out using uncured, compounded samples using a Monsanto Moving Die Rheometer (MDR) Model 2000 from Monsanto Company, Saint Louis, Mo., in accordance with ASTM D 5289-93a “Standard Test Method for Rubber Property—Vulcanization Using Rotorless Cure Meters” at 100° C., no pre-heat, 15 minute elapsed time, and a 0.5 degree arc. Both the minimum torque (M_{L}) and the highest torque attained during a specified period of time when no plateau or maximum torque (M_{H}) was obtained were measured. Also measured were the time for the torque to increase 2 units above M_{L} (tₛ2), the time for the torque to reach a value equal to M_{L}+0.5(M_{H}−M_{L}), (t′50), and the time for the torque to reach M_{L}+0.9(M_{H}−M_{L}), (t′90) as well as the tan(delta) at M_{L} and M_{H}. Tan(delta) is equal to the ratio of the tensile loss modulus to the tensile storage modulus (lower tan(delta) means more elastic). Results are reported in Table 2.

### Post-Curing and Physical Property Testing

The compounded samples were cut into sheets 15 cm×15 cm×2 mm and placed in an oven at 100° C. on a 100° C. preheated metal plate for 15 minutes. A visual observation for any surface air bubbles was recorded and reported in Table 2. Dumbbells for physical properties were cut from the cured sheets with ASTM D412 “Tensile Strength Properties of Rubber and Elastomers” Die D. The post-cured samples were tested for physical properties: tensile strength, elongation, 100% modulus, and Shore Hardness A in accordance with ASTM D 412-06a (2013) “Standard Test Methods for Vulcanized Rubber and Thermoplastic Elastomers—Tension”.

### General Compounding Procedure

The polymers were compounded on a two-roll mill with materials as described in Table 2 and tested per the Cure Rheology Testing and Post-Curing and Physical Property Testing sections above. Results are reported in Table 2.

### General Compounding Procedure

Fluoropolymer precursor compositions were compounded and tested as per GENERAL COMPOUNDING PROCEDURE, CURE RHEOLOGY TESTING and POST-CURING AND PHYSICAL PROPERTY TESTING as reported in Table 2. As can be seen from Comparative Examples A-C peroxides other than bis(2,4-dichlorobenzoyl) peroxide resulted in, after curing under ambient pressure conditions, a surface characterized by at least 5 area percent of surface bubbles. In Table 2, “Y”=yes and “N”=no.

TABLE 2

| | EXAMPLE | | | | | | | |
|---|---|---|---|---|---|---|---|---|
| | CE A | CE B | CE C | CE D | EX 1 | EX 2 | EX 3 | EX 4 |
| Fluoropolymer, | D, | D, | D, | D, | A, | D, | B, | B, |
| phr | 100 | 100 | 100 | 100 | 100 | 100 | 100 | 100 |
| Peroxide, | B, | C, | D, | A, | A, | A, | A, | A, |
| phr | 5 | 5 | 6.3 | 5 | 5 | 5 | 5 | 5 |
| Filler, | talc, | talc, | talc, | talc, | BS, | BS, | BS, | silica |
| phr | 18 | 18 | 18 | 18 | 55 | 55 | 55 | 35 |
| phr of | 5 | 5 | 5 | 5 | 3 | 5 | 5 | 5 |
| Coagent | | | | | | | | |
| phr of | 1 | 1 | 1 | 1 | 1 | 1 | 1 | 1 |
| Process Aid | | | | | | | | |
| phr of | 8 | 8 | 8 | 0 | 8 | 8 | 8 | 8 |
| Zeolite 4A | | | | | | | | |
| phr of | 1 | 1 | 1 | 0 | 1 | 1 | 1 | 1 |
| CaO | | | | | | | | |
| MDR 12 min/ | | | | | | | | |
| 100° C. | | | | | | | | |
| M_{L} dN-m | 4.26 | 4.60 | 2.97 | 2.81 | 0.07 | 4.02 | 2.62 | 2.46 |
| (lb-in) | (3.77) | (4.07) | (2.63) | (2.49) | (0.062) | (3.56) | (2.32) | (2.18) |
| M_{H} dN-m | 4.76 | 4.79 | 16.05 | 12.78 | 9.80 | 18.76 | 16.16 | 17.63 |
| (lb-in) | (4.21) | (4.24) | (14.2) | (11.31) | (8.67) | (16.6) | (14.3) | (15.6) |
| M_{H} − M_{L} | 0.44 | 0.17 | 11.6 | 8.82 | 9.70 | 13.1 | 12.0 | 13.4 |
| tₛ2, min | — | — | 3.49 | 0.96 | 1.10 | 0.95 | 1.10 | 1.01 |
| t′50, min | 1.71 | 1.21 | 6.35 | 1.43 | 1.60 | 1.60 | 1.77 | 1.71 |
| t′90, min | 6.11 | 2.34 | 10.4 | 3.73 | 4.50 | 4.31 | 4.58 | 4.27 |
| Tan(delta) at | 0.66 | 0.65 | 0.76 | 0.71 | 4.60 | 0.697 | 0.698 | 0.739 |
| M_{L} | | | | | | | | |
| Tan(delta) at | 0.65 | 0.63 | 0.21 | 0.21 | 0.40 | 0.201 | 0.171 | 0.175 |
| M_{H} | | | | | | | | |
| Physical | | | | | | | | |
| Properties | | | | | | | | |
| tensile strength, | — | — | 5.6 | 8.1 | 2.3 | 6.5 | 3.7 | 6.2 |
| MPa | | | | | | | | |
| elongation, % at | — | — | 362 | 436 | 262 | 494 | 421 | 475 |
| break | | | | | | | | |
| 100% modulus, | — | — | 2.6 | 2.8 | 1.1 | 2 | 1.1 | 1.7 |
| MPa | | | | | | | | |
| Shore | — | — | 56 | 62 | 48 | 64 | 44 | 50 |
| Hardness A | | | | | | | | |
| ≧95 Area | N | N | N | N | Y | Y | Y | Y |
| Percent Free of | | | | | | | | |
| Surface | | | | | | | | |
| Bubbles | | | | | | | | |
| when Cured at | | | | | | | | |
| Ambient | | | | | | | | |
| Pressure for | | | | | | | | |
| 15 min at 100° C. | | | | | | | | |
| ≧95 Volume | N | N | N | N | Y | Y | Y | Y |
| Percent Free of | | | | | | | | |
| Interior | | | | | | | | |
| Bubbles | | | | | | | | |
| when Cured at | | | | | | | | |
| Ambient | | | | | | | | |
| Pressure for | | | | | | | | |
| 15 min at 100° C. | | | | | | | | |
| | EXAMPLE | | | | | | | |
| | EX 5 | EX 6 | EX 7 | EX 8 | EX 9 | EX 10 | EX 11 | EX 12 |
| Fluoropolymer, | B, | D, | D, | D, | D, | C, | E, | D, |
| phr | 100 | 100 | 100 | 100 | 100 | 100 | 100 | 100 |
| Peroxide, | A, | A, | A, | A, | A, | A, | A, | A, |
| phr | 5 | 5 | 5 | 5 | 5 | 5 | 5 | 5 |
| Filler, | silica | BS, | CaSil | CaCO₃ | talc | silica | silica | FC |
| phr | 15 | 55 | 33 | 33 | 18 | 35 | 35 | 25 |
| phr of | 5 | 5 | 5 | 5 | 5 | 5 | 5 | 5 |
| Coagent | | | | | | | | |
| phr of | 1 | 1 | 1 | 1 | 1 | 1 | 1 | 1 |
| Process Aid | | | | | | | | |
| phr of | 8 | 8 | 8 | 8 | 8 | 8 | 8 | 8 |
| Zeolite 4A | | | | | | | | |
| phr of | 1 | 1 | 1 | 1 | 1 | 1 | 1 | 1 |
| CaO | | | | | | | | |
| MDR 12 min/ | | | | | | | | |
| 100° C. | | | | | | | | |
| M_{L} dN-m | 4.35 | 3.67 | 3.60 | 4.99 | 3.92 | 3.56 | 8.40 | 7.31 |
| (lb-in) | (3.85) | (3.25) | (3.19) | (4.42) | (3.47) | (3.15) | (7.43) | (6.47) |
| M_{H} dN-m | 28.36 | 18.87 | 19.55 | 19.32 | 19.89 | 13.90 | 27.91 | 25.22 |
| (lb-in) | (25.1) | (16.7) | (17.3) | (17.1) | (17.6) | (12.3) | (24.7) | (22.32) |
| M_{H} − M_{L} | 21.2 | 13.4 | 14.1 | 12.6 | 14.1 | 9.11 | 17.3 | 15.85 |
| tₛ2, min | 0.93 | 0.86 | 0.77 | 0.91 | 0.77 | 0.64 | 0.49 | 1.24 |
| t′50, min | 1.68 | 1.58 | 1.45 | 1.77 | 1.36 | 0.91 | 0.66 | 2.41 |
| t′90, min | 4.48 | 4.55 | 4.41 | 4.98 | 3.70 | 2.47 | 2.80 | 6.49 |
| Tan(delta) at | NM | 0.78 | 0.75 | 0.69 | 0.68 | 0.47 | 0.45 | 0.57 |
| M_{L} | | | | | | | | |
| Tan(delta) at | NM | 0.21 | 0.20 | 0.20 | 0.22 | 0.20 | 0.23 | 0.17 |
| M_{H} | | | | | | | | |
| Physical | | | | | | | | |
| Properties | | | | | | | | |
| tensile strength, | NM | 4.5 | 6.2 | 4.9 | 7.4 | 2.7 | 4.0 | 10.6 |
| MPa | | | | | | | | |
| elongation, % at | NM | 336 | 374 | 318 | 328 | 231 | 129 | 363 |
| break | | | | | | | | |
| 100% modulus, | NM | 1.9 | 2.3 | 2.4 | 3.8 | 1.8 | 3.7 | 3.5 |
| MPa | | | | | | | | |
| Shore | NM | 46 | 42 | 42 | 59 | 52 | 59 | 62 |
| Hardness A | | | | | | | | |
| ≧95 Area | Y | Y | Y | Y | Y | Y | Y | Y |
| Percent Free of | | | | | | | | |
| Surface | | | | | | | | |
| Bubbles | | | | | | | | |
| when Cured at | | | | | | | | |
| Ambient | | | | | | | | |
| Pressure for | | | | | | | | |
| 15 min at 100° C. | | | | | | | | |
| ≧95 Volume | Y | Y | Y | Y | Y | Y | Y | Y |
| Percent Free of | | | | | | | | |
| Interior | | | | | | | | |
| Bubbles | | | | | | | | |
| when Cured at | | | | | | | | |
| Ambient | | | | | | | | |
| Pressure for | | | | | | | | |
| 15 min at 100° C. | | | | | | | | |

All cited references, patents, or patent applications in the above application for letters patent are herein incorporated by reference in their entirety in a consistent manner. In the event of inconsistencies or contradictions between portions of the incorporated references and this application, the information in the preceding description shall control. The preceding description, given in order to enable one of ordinary skill in the art to practice the claimed disclosure, is not to be construed as limiting the scope of the disclosure, which is defined by the claims and all equivalents thereto.

1-23. (canceled)

24. A method of making a fluoroelastomer composition, the method comprising curing a fluoroelastomer precursor composition under pressure in the range of from 0.9 to 1.1 bar to provide the fluoroelastomer composition, wherein the fluoroelastomer precursor composition comprises:
at least one peroxide-curable fluoropolymer;
from 1 to 8 percent by weight, based on the total weight of the fluoroelastomer precursor composition, of peroxide for curing the at least one peroxide-curable fluoropolymer, wherein the peroxide consists essentially of bis(2,4-dichlorobenzoyl) peroxide,
wherein the fluoroelastomer precursor composition further comprises at least one filler selected from the group consisting of alkali metal carbonates, alkali metal sulfates, alkaline earth metal carbonates, alkaline earth metal sulfates, alkali metal oxides, alkaline earth metal oxides, titanium oxides, silicon oxides, alkali metal silicates, alkaline earth silicates, fluorinated carbon particles, and combinations thereof, wherein the fluoroelastomer composition is essentially free of non-fluorinated carbon particles, wherein the fluoroelastomer composition has a surface, and wherein at least 95 area percent of the surface of the fluoroelastomer composition is free of bubbles having a maximum diameter larger than 0.5 mm immediately adjacent to the surface and is free of surface cavities having a maximum dimension larger than 0.5 mm.

25. A method of making a fluoroelastomer composition according to claim 24, wherein the peroxide-curable fluoroelastomer precursor composition comprises a fluoropolymer comprising interpolymerized monomer units, and wherein the monomer units comprise at least one of tetrafluoroethylene, vinylidene fluoride, hexafluoropropylene, ethylene, propylene, perfluorinated alkyl vinyl ethers, perfluorinated allyl ethers, chlorotrifluoroethylene, vinyl fluoride, and trifluoroethylene.

26. A method of making a fluoroelastomer composition according to claim 24, wherein said curing the fluoroelastomer precursor composition is effected by heating the fluoroelastomer precursor composition at at least one temperature in the range of from 40° C. to 150° C.

27. A method of making a fluoroelastomer composition according to claim 24, wherein the fluoroelastomer precursor composition is essentially free of carbon black.

28. A method of making a fluoroelastomer composition according to claim 24, wherein the fluoroelastomer composition is substantially free of interior bubbles.

29. A method of making a fluoroelastomer composition according to claim 24, wherein said curing the fluoroelastomer precursor composition is carried out in a hot air tunnel.

30. A method of making a fluoroelastomer composition according to claim 24, further comprising extruding the fluoroelastomer precursor composition.

31. A method of making a fluoroelastomer composition according to claim 24, wherein said curing the fluoroelastomer precursor composition is carried out in an open mold.

32. A method of making a composite article, the method comprising:
disposing a layer of a fluoroelastomer precursor composition on at least a portion of at least one surface of a substrate, wherein the fluoroelastomer precursor composition comprises:
at least one peroxide-curable fluoropolymer;
from 1 to 8 percent by weight, based on the total weight of the fluoroelastomer precursor composition, of peroxide for curing the at least one peroxide-curable fluoropolymer, wherein the peroxide consists essentially of bis(2,4-dichlorobenzoyl) peroxide,
wherein the fluoroelastomer precursor composition further comprises at least one filler selected from the group consisting of alkali metal carbonates, alkali metal sulfates, alkaline earth metal carbonates, alkaline earth metal sulfates, alkali metal oxides, alkaline earth metal oxides, titanium oxides, silicon oxides, alkali metal silicates, alkaline earth silicates, fluorinated carbon particles, and combinations thereof.
wherein the fluoroelastomer composition is essentially free of non-fluorinated carbon particles; and
curing the fluoroelastomer precursor composition to provide a fluoroelastomer composition,
wherein the fluoroelastomer composition has a surface, and wherein at least 95 area percent of the surface of the fluoroelastomer composition is free of bubbles having a maximum diameter larger than 0.5 mm immediately adjacent to the surface and is free of surface cavities having a maximum dimension larger than 0.5 mm.

33. A method of making a composite article according to claim 32, wherein the substrate comprises a carrier film.

34. A method of making a composite article according to claim 32, wherein the filler comprises fluorinated carbon particles.

35. A method of making a composite article according to claim 32, wherein the peroxide-curable fluoroelastomer precursor composition comprises a fluoropolymer comprising interpolymerized monomer units, and wherein the monomer units comprise at least one of tetrafluoroethylene, vinylidene fluoride, hexafluoropropylene, ethylene, propylene, perfluorinated alkyl vinyl ethers, perfluorinated allyl ethers, chlorotrifluoroethylene, vinyl fluoride, and trifluoroethylene.

36. A method of making a composite article according to claim 32, wherein said curing the fluoroelastomer precursor composition is effected by heating the fluoroelastomer precursor composition at at least one temperature in the range of from 40° C. to 150° C.

37. A method of making a composite article according to claim 32, wherein said curing of the fluoroelastomer precursor composition occurs at a pressure in the range of from 0.9 to 1.1 bar (90 to 110 kPa).

38. A method of making a composite article according to claim 32, wherein the fluoroelastomer composition is substantially free of interior bubbles.
